(19) United States
(12) Patent Application Publication
(10) Pub. No.: US 2026/0319375 A1
(43) Pub. Date: Oct. 15, 2026

(54) Two-Color Projection Lithography with Wavevector-Filtered Deactivation Imaging

(71) Applicant: Enterprise Science Fund, LLC, Bellevue, WA (US)

(72) Inventor: Matthew N. Julian, Oakton, VA (US)

(73) Assignee: Enterprise Science Fund, LLC, Bellevue, WA (US)

(21) Appl. No.: 19/637,695

(22) Filed: Apr. 2, 2026

Related U.S. Application Data
(60) Provisional application No. 63/786,092, filed on Apr. 9, 2025.

(51) Int. Cl. G03F 7/00

(52) U.S. Cl. CPC G03F 7/70308; G03F 7/7005; G03F 7/70258; G03F 7/70283; G03F 7/70325

(57) ABSTRACT

Systems, methods, and masks are disclosed for achieving sub-diffraction-limited patterning in projection lithography by integrating wavevector-based optical filters into a multi-wavelength (two-color) exposure process. In various examples, a first beam (an activation beam) is focused, while a spatially filtered second beam (a deactivation beam) exhibits an edge-emphasizing profile, thereby narrowing the exposed regions beyond conventional diffraction limits. The system may selectively block or enhance specific spatial frequencies of the projected image. For example, a spatial filter, such as a second-order differentiation filter or another tailored wavevector response, may be positioned behind the mask or at a conjugate image plane. The deactivation pattern may be configured to closely overlap the focal area of the activation beam, thereby reducing the feature sizes in the final lithographic pattern.

### RELATED APPLICATIONS

This application claims priority to and benefit under 35 U.S.C. § 119 to U.S. Provisional Patent Application 63/786,092, filed on Apr. 9, 2025, titled “Wavevector Filtering For Projection-Based Super Resolution Lithography,” which is hereby incorporated by reference in its entirety.

### TECHNICAL FIELD

This disclosure relates to lithographic masks and lithography. This disclosure particularly relates to projection lithography and two-color lithographic approaches for activation and deactivation.

### BRIEF DESCRIPTION OF THE DRAWINGS

FIG. 1 illustrates a conceptual block diagram of a two-color lithographic architecture, according to one embodiment.

FIG. 2 illustrates a block diagram of a projection lithography system with two distinct optical arms for activation and deactivation, according to one embodiment.

FIG. 3 illustrates a block diagram of a projection lithography system with a common path for activation and deactivation optical radiation, according to one embodiment.

FIG. 4 illustrates example exposure widths for single-color and two-color lithographic systems, according to one embodiment.

FIG. 5 illustrates an example transfer function, point spread function, and exposure characteristics for a two-color lithographic system, according to one embodiment.

FIG. 6 illustrates example dense-pitch phase-delay arrangements and corresponding pattern-fidelity characteristics, according to one embodiment.

FIG. 7A illustrates example performance characteristics of an unoptimized binary mask, according to one embodiment.

FIG. 7B illustrates example performance characteristics of an unoptimized trinary mask, according to one embodiment.

FIG. 8 illustrates an example inverse-designed mask and exposure solutions for a target pattern, according to one embodiment.

FIG. 9 illustrates a method of forming a feature in a photosensitive layer using two-color projection lithography, according to one embodiment.

FIG. 10 illustrates a method of forming a feature in a photosensitive layer using a pupil-associated optical shaping element, according to one embodiment.

### DETAILED DESCRIPTION

Projection lithography transfers a pattern from a mask to a photosensitive layer through projection optics. As feature sizes continue to shrink, diffraction associated with the exposure wavelength and the projection optics can constrain the minimum feature size that can be printed. Reducing feature size while preserving throughput, field size, and overlay performance remains a significant consideration in the design of lithographic systems.

In some multiple-wavelength lithography approaches, a pattern may be formed by scanning a focused beam across a substrate. Translating an activation/deactivation imaging concept to projection lithography presents different constraints because a projection system images an extended mask pattern having multiple neighboring features rather than a single isolated spot. In such projection-format systems, the optical response may be selected so that a deactivation image narrows a corresponding activation image while neighboring features in a periodic or dense-pitch pattern remain sufficiently separated to preserve feature fidelity and avoid unwanted overlap.

Various systems, methods, devices, and mask assemblies for projection lithography are described herein. For example, projection lithography systems are described herein for forming a feature in a photosensitive layer on a substrate. In various embodiments, projection lithography systems are described that include one or more of a mask defining a pattern, a first radiation source configured to provide optical radiation at a first wavelength, and a second radiation source configured to provide optical radiation at a second wavelength different from the first. The projection lithography system may further include projection optics to project from the mask a first patterned image at the first wavelength and a second patterned image at the second wavelength onto the photosensitive layer in a spatially registered relationship. An optical filter having a wavevector-dependent transfer function may be disposed in an optical path of the second optical radiation. In such embodiments, the optical filter receives, at the second wavelength, an optical field patterned by the mask. The optical filter modifies the spatial-frequency content of that optical field such that the second patterned image has an edge-emphasizing intensity profile derived from the pattern and overlapping edge regions of the first patterned image. Superposition of the first and second patterned images on the photosensitive layer suppresses exposure in the edge regions of the first patterned image, leaving a narrower exposure region than the projection of the first patterned image alone could achieve.

In some embodiments, the first patterned image is an activation image, and the second patterned image is a deactivation image. Overlap of the activation and deactivation images narrows the exposed region relative to exposure by the activation image alone, yielding a feature with dimensions below the diffraction-limited dimensions achievable with the activation image alone. In some embodiments, the system exposes the photosensitive layer by projecting the first and second patterned images in a single (e.g., shared) exposure operation, so that the second patterned image suppresses exposure in the edge regions of the first patterned image.

In some embodiments, the optical filter is positioned adjacent to the mask (e.g., disposed directly behind the mask). In some embodiments, the optical filter is positioned at an image plane optically conjugate to the mask, so that the filtered second-wavelength image remains derived from the mask pattern, while the spatial-frequency response of the filter shapes the corresponding deactivation image. In some embodiments, the projection optics include a first optical train and a second optical train configured to respectively project the first patterned image and the second patterned image. In these embodiments, the second optical train includes the optical filter, whereas the optical filter is omitted from the first optical train. In some embodiments, the first optical train and the second optical train are configured to simultaneously project the first patterned image and the second patterned image onto the photosensitive layer (rather than being raster-scanned). In some embodiments, the system further includes an alignment subsystem configured to maintain registration between the first and second patterned images on the photosensitive layer. In some embodiments, the alignment subsystem is configured to periodically realign the first and second patterned images between exposure operations.

In some embodiments, the optical filter includes a single optical element disposed in a common optical train for the first optical radiation and the second optical radiation. The single optical element has a first transfer function at the first wavelength and a second transfer function at the second wavelength. The first transfer function passes first-wavelength radiation (patterned by the mask) substantially without spatial-frequency filtering. The second transfer function spatially filters second-wavelength radiation (patterned by the mask) to generate the edge-emphasizing intensity profile of the second patterned image. In some embodiments, the single optical element includes an aperiodic thin-film filter (e.g., with multiple layers).

In some embodiments, the single optical element common to the first and second optical radiation has a first wavelength response that passes the first optical radiation substantially without augmentation and a second wavelength response that produces a point spread function configured to cancel edge portions of the pattern defined by the mask. In some embodiments, the single optical element comprises a thin-film filter, a metasurface, or another wavelength-selective structure disposed in a common optical train, such that the second patterned image suppresses edge exposure while the first patterned image remains substantially unmodified. In some embodiments, use of the single optical element reduces or eliminates alignment error that might otherwise arise between separate activation and deactivation optical trains.

In some embodiments, the optical filter is configured to implement a high-pass spatial filter that approximates a second-order spatial derivative of the pattern. In some embodiments, the second patterned image exhibits a double-hump intensity distribution along the edge of a mask feature, with an intensity minimum at the edge. Such a spatial response can provide a mask-derived edge map that overlaps the first patterned image, thereby suppressing exposure at the edges of the first patterned image.

In some embodiments, the optical filter includes a periodic metasurface. In some embodiments, the optical filter includes a thin-film filter comprising a plurality of layers. In some embodiments, the optical filter is inverse-designed to provide the second patterned image with a profile corresponding to a desired patterning resolution. These filter implementations permit the transfer function of the second-wavelength path to be tailored to a desired edge-emphasizing response while maintaining compatibility with projection lithography. In some embodiments in which the optical filter is positioned at the conjugate image plane, the optical filter includes a spiral phase plate configured to generate, at the second wavelength, a point spread function having a central intensity minimum and an annular intensity distribution. In such embodiments, the filtered second-wavelength image provides a depletion-like distribution derived from the mask pattern and overlapping the first patterned image, thereby narrowing the effective exposure region.

In another aspect, a projection lithography apparatus includes a mask defining a pattern, a first radiation source configured to provide first optical radiation at a first wavelength, a second radiation source configured to provide second optical radiation at a second wavelength different from the first wavelength, a first optical train configured to project a first patterned image at the first wavelength onto the photosensitive layer, and a second optical train configured to project a second patterned image at the second wavelength onto the photosensitive layer. The first optical train does not include an optical filter. The second optical train includes an optical filter having a wavevector-dependent transfer function configured to receive a mask-patterned optical field at the second wavelength and to modify the spatial-frequency content of that optical field such that the second patterned image has an edge-emphasizing intensity profile derived from the pattern. The apparatus further includes an alignment subsystem configured to maintain registration between the first and second patterned images on the photosensitive layer. Superposition of the first patterned image and the second patterned image suppresses exposure at edge regions of the first patterned image and leaves a narrower exposure region than the projection of the first patterned image alone.

In some embodiments of the apparatus, the first patterned image is an activation image and the second patterned image is a deactivation image. In some embodiments, the first optical train and the second optical train are configured to simultaneously project the first patterned image and the second patterned image onto the photosensitive layer. In some embodiments, the alignment subsystem is configured to periodically realign the first and second patterned images between exposure operations. In some embodiments, the optical filter is disposed behind the mask in the second optical train (e.g., directly behind the mask). In some embodiments, the optical filter is positioned at an image plane optically conjugate to the mask in the second optical train. In some embodiments, the optical filter implements a high-pass spatial filtering operation that approximates a second-order spatial derivative of the pattern (e.g., the second patterned image may exhibit a double-hump intensity distribution along the edge of a mask feature). In some embodiments, the optical filter includes a periodic metasurface. In some embodiments, the optical filter includes a thin-film filter comprising a plurality of layers. In some embodiments, the optical filter includes a spiral phase plate configured to generate, at the second wavelength, a point spread function having a central intensity minimum and an annular intensity distribution.

In another aspect, a lithographic mask assembly for two-color projection lithography includes a mask defining a pattern and an optical filter disposed behind the mask. The optical filter may have a wavevector-dependent transfer function and is configured to receive and modify the spatial-frequency content of the optical field of the patterned optical field at the second wavelength, resulting in an edge-emphasized intensity profile. When used in a projection lithography system, the mask assembly provides a mask-derived deactivation image that overlaps the edge regions of an activation image of the same pattern at a different wavelength, thereby suppressing exposure at the edge regions and narrowing the effective exposure region relative to the projection of the activation image alone.

In various embodiments, effective spatial filtering in a projection lithography system may depend on both filter placement and mask phase distribution. In some embodiments, filtering may be implemented in object or image space, such as at the mask or at a plane optically conjugate to the mask; in Fourier space, such as at a pupil plane or an aperture-stop plane; or in both locations. For dense patterns and multiple wavelengths, the phase distribution across the mask may be selected using modeling or inverse design so that the mask and optical filters cooperate simultaneously at the different wavelengths to suppress interference fringes, maintain pattern density, and provide a desired exposure profile.

A projection lithography system may be configured to form a feature in a photosensitive layer on a substrate. The system may include a mask defining a pattern, a first radiation source configured to provide first optical radiation at a first wavelength, and a second radiation source configured to provide second optical radiation at a second wavelength. The system may further include projection optics to project from the mask a first patterned image at the first wavelength and a second patterned image at the second wavelength onto the photosensitive layer in a spatially registered relationship. The system may further include at least one optical shaping element disposed at a pupil-associated plane of the projection optics, such as a pupil plane, a Fourier plane, or an aperture stop plane, in an optical path of the second optical radiation. The optical shaping element shapes the second optical radiation such that the second patterned image has a spatial intensity profile different from that of the first patterned image, and the superposition of the first and second patterned images leaves a narrower exposure region than the projection of the first patterned image alone.

In some embodiments, the projection optics comprise a first optical arm configured to project the first patterned image and a second optical arm configured to project the second patterned image. Each optical arm includes a respective tube lens. The first optical arm and the second optical arm may be combined by a beam splitter upstream of an objective lens, and the second optical arm may include an aperture stop and one or more phase/amplitude control elements at a pupil-associated plane of the projection optics. In some embodiments, the phase/amplitude control elements include a spiral phase plate and/or an apodizing intensity filter arranged as a pupil-plane stack for shaping the second optical radiation.

In some embodiments, the first optical arm includes a mask positioned with respect to a wavevector filter in the image plane of the respective tube lens, and an aperture stop in the pupil plane of that tube lens, to limit the allowed wavevectors entering the system. In some embodiments, the second optical arm includes a corresponding mask and a deactivation filter in an image plane of a second tube lens, together with the pupil-plane phase/amplitude control elements, so that the two optical arms cooperatively project activation and deactivation images of the same pattern onto the substrate.

In some embodiments, the first optical radiation and the second optical radiation are co-propagating through a common optical train including a common mask and a common optical shaping structure before being projected onto the substrate. In some embodiments, the common optical shaping structure includes a common wavevector filter, a common spiral phase plate and apodizing filter arrangement, and/or a wavelength-selective element configured such that the first-wavelength radiation passes substantially without augmentation while the second-wavelength radiation is shaped to suppress edge exposure. In some embodiments, an additional wavevector filter is positioned at the mask or at a plane optically conjugate to the mask, while a spiral phase plate is positioned at a pupil plane or Fourier plane of the projection optics. In some embodiments, an apodizing intensity filter is used in conjunction with the spiral phase plate in the deactivation path so that shaping at the mask plane and shaping at the pupil-associated plane are jointly selected to obtain a desired deactivation profile and patterning resolution.

In some embodiments, the mask is a simultaneous phase-and-amplitude mask configured to modulate amplitude and phase at both the first and second wavelengths to improve pattern density. In such embodiments, phase and amplitude variation at the mask level are selected to reduce deactivation-beam tail outside the desired exposure area by destructive interference, open transmissive regions of the mask may have phase delays corresponding to integer multiples between 0 and 2π, phase-shift elements may be binary, ternary, or higher-order phase steps, and the amplitude profile of the mask need not be restricted to a nominal profile directly matching the target pattern.

In some embodiments, the optical shaping elements are configured to implement an optimized amplitude transfer function for the deactivation path, such as an optimized radially symmetric amplitude transfer function that produces a target point spread function including a center-depleted or annular distribution. In some embodiments, relative activation/deactivation intensities are selected to obtain a target feature width or exposure full width at half maximum. As a specific example, joint optimization of the mask phase-and-amplitude distribution and the projection-system point spread function can provide single-exposure line spacings down to about λ/2NA, where λ is the deactivation-beam wavelength, and NA is the numerical aperture of the projection optics. In this non-limiting example, the system can provide lithographic feature sizes corresponding to a resolution pre-factor k1 of about 0.06 and below with sub-diffraction-limited feature density.

In some embodiments, a single mask is co-optimized for both activation and deactivation wavelengths in a shared activation/deactivation beam path, and in other embodiments, separate masks in split beam paths are co-optimized with one another and with filters in the mask plane and the Fourier plane. In some embodiments, the mask introduces phase differences between adjacent transmissive regions corresponding to adjacent patterned features in a dense-pitch region, thereby improving feature density and pitch fidelity. In more specific embodiments, approximately π phase differences are introduced between at least some adjacent features, and mask phase distributions are inverse-designed for a target pattern. The phase arrangement may be selected by evaluating an overlap quality metric (e.g., an intersection-over-union metric) as a function of pitch.

In another aspect, a method of forming a feature in a photosensitive layer on a substrate using projection lithography includes projecting from a mask a first patterned image at a first wavelength and a second patterned image at a second wavelength onto the photosensitive layer in registration, disposing at least one optical shaping element at a pupil-associated plane of the projection optics in an optical path of the second optical radiation, shaping the second optical radiation at the pupil-associated plane to produce a spatial intensity profile different from that of the first patterned image, and superposing the first patterned image and the second patterned image to leave a narrower exposure region than projection of the first patterned image alone. In some embodiments, the method further includes jointly optimizing the mask phase-and-amplitude distribution with one or more filters in the mask plane and/or the Fourier plane to improve dense-pitch fidelity and feature density.

In another aspect, a lithographic mask article for use in two-color projection lithography includes a patterned region configured to modulate amplitude and phase at both the first and second wavelengths and to be co-optimized with at least one optical shaping element disposed at a pupil-associated plane of projection optics. When used in a projection lithography system, the mask article forms first and second patterned images in registration at the substrate, the second patterned image having a shaped deactivation profile selected in cooperation with the mask phase and amplitude distribution to leave a narrower exposure region, improve dense-pitch performance, and increase printable feature density relative to a corresponding non-optimized mask.

Wavevector-based filters perform mathematical operations on the spatial frequencies of the optical radiation. A wavevector-based filter forms an image as a convolution of the optical radiation and a point spread function (PSF) of the filter, PSF(x, y). The filter function can also be understood in terms of an amplitude transfer function, ATF(kₓ, k_{y}), where ATF(kₓ, k_{y})=FT[PSF(x, y)]. One example of a filter is one that implements a second-order derivative by using an ATF proportional to the square of the in-plane wavevector

$$( ATF ∝ {k}_{x}^{2} ) ,$$

or, more generally, to the square of the in-plane wavevector magnitude. The filter may serve as a high-pass spatial filter, blocking low-frequency components while passing high-frequency components. The result is an edge-emphasized image that matches the edges of the original image. In some embodiments, filters are used with even functions, such as second- and fourth-order derivatives, since these filters are symmetric in ±k_{x,y}, and thus do not require asymmetry in the direction of propagation. Various filter functions can be achieved using either periodic metasurfaces and/or layers of thin films. Variations of wavevector-based filters may be implemented to be narrowband and designed for coherent light. Incoherent designs are also possible in which the PSF (an intensity function for incoherent light) has all positive values.

As used herein, “optical radiation,” “radiation,” “light,” and similar terms refer broadly to electromagnetic radiation usable for pattern formation, imaging, exposure, inspection, filtering, alignment, and/or related optical operations. Optical radiation may include, for example, ultraviolet, deep ultraviolet, extreme ultraviolet, visible, infrared, and/or other wavelength bands, and may be coherent, partially coherent, or incoherent, unless a particular coherence condition is expressly stated. As used herein, a “mask” may include any pattern-defining element, reticle, photomask, phase mask, amplitude mask, phase-and-amplitude mask, grayscale mask, transmissive mask, reflective mask, and/or other structure configured to define, modulate, encode, or otherwise impose a spatial pattern on optical radiation. A “pattern” may include one or more isolated features, periodic features, dense-pitch features, two-dimensional features, line space patterns, contact patterns, curvilinear features, and/or any other desired spatial arrangement.

As used herein, a “photosensitive layer” may include any photoresist, photoactive material, chemically amplified resist, non-chemically amplified resist, imaging layer, hard-mask stack, underlayer, multilayer resist structure, and/or other material whose state, chemistry, solubility, activation, deactivation, exposure threshold, or development behavior is affected by optical radiation. A “substrate” may include a wafer, semiconductor substrate, glass substrate, panel, workpiece, intermediate structure, and/or any other support on or in which a feature is to be formed. As used herein, “projection optics,” “optical train,” “optical arm,” and similar terms refer broadly to one or more optical components configured to receive patterned radiation and to form a corresponding image at a target plane. Such components may include one or more lenses, mirrors, objectives, tube lenses, relay optics, beam splitters, dichroic elements, apertures, stops, alignment elements, and/or other optical components. A “common optical train” refers to an optical path shared by different wavelengths for at least a portion of their propagation. Separate optical trains or optical arms may share one or more downstream optical elements.

As used herein, an “optical filter,” “wavevector-based optical filter,” “spatial filter,” and/or “optical shaping element” may include any element or combination of elements configured to alter the spatial-frequency content, point spread function, amplitude transfer function, phase transfer function, polarization response, and/or image-forming behavior of optical radiation. Examples may include metasurfaces, thin-film filters, multilayer filters, aperiodic thin-film structures, phase plates, spiral phase plates, apodizing filters, aperture-plane elements, pupil-plane elements, Fourier-plane elements, image-plane elements, and/or wavelength-selective structures. An optical filter may be implemented as a single element, a stack, a distributed structure, or multiple spaced-apart elements.

As used herein, “wavevector,” “spatial frequency,” “k-space,” “Fourier space,” and similar terms refer generally to angular and/or spatial-frequency content of an optical field. A “wavevector-dependent transfer function” may refer to any amplitude, phase, complex, or other transfer function that varies with spatial frequency and that influences the formation of a filtered image, edge-enhanced image, annular distribution, center-depleted distribution, derivative-like response, and/or other desired optical response.

As used herein, “pupil-associated plane” may include a pupil plane, Fourier plane, aperture-stop plane, and/or any plane optically related to angular or spatial-frequency content of the optical radiation. An “image plane optically conjugate to the mask” may include any plane that is optically conjugate to the mask or to a mask image, whether intermediate or final, and whether magnified, reduced, inverted, relayed, or otherwise transformed by the optical system. References to placement “adjacent” a mask include placement directly behind, directly in front of, in contact with, immediately proximate to, or otherwise sufficiently near the mask to receive optical radiation patterned by the mask.

As used herein, “registration,” “spatial registration,” “aligned,” and similar terms refer to a desired spatial relationship between two or more images, fields, patterns, or exposure distributions. Such registration need not be mathematically perfect and may instead be aligned within a selected tolerance, threshold, or overlap criterion. “Maintain registration,” “restore registration,” and “realign” include active and passive techniques, manual and automatic techniques, periodic and continuous techniques, and open-loop and closed-loop techniques.

As used herein, “activation image,” “deactivation image,” and similar terms refer to images, fields, or exposures that respectively promote and suppress a net patterning response in a photosensitive layer. These terms do not require or imply any particular resist chemistry, thresholding mechanism, nonlinear effect, or sequence of operation unless expressly stated. Likewise, an “edge-emphasizing” image or intensity profile may include an edge map, derivative-like response, second-order derivative response (e.g., a double-hump response), annular response, center-depleted response, donut-like response, and/or any other profile that preferentially affects edge regions relative to a corresponding unfiltered image.

As used herein, “inverse design,” “optimization,” “co-optimization,” “modeled,” “simulated,” and similar terms refer broadly to selecting one or more optical, geometrical, material, phase, amplitude, mask, filter, and/or system parameters based on one or more target criteria. Such criteria may include feature width, pitch fidelity, edge overlap, process window, exposure threshold, full width at half maximum, intersection-over-union, contrast, manufacturability, throughput, robustness, and/or other performance measures. Any described modeling, simulation, optimization, and/or design procedure is illustrative and may be performed using analytical, numerical, empirical, heuristic, machine-learning-based, inverse-design, and/or hybrid techniques.

The figures and their corresponding descriptions are illustrative and not necessarily drawn to scale. Relative dimensions, spacing, feature sizes, layer thicknesses, field distributions, and angular relationships shown in the figures may be exaggerated, simplified, idealized, and/or schematic for clarity. Functional blocks, optical elements, filters, masks, planes, and other components shown in the figures may be rearranged, combined, subdivided, duplicated, omitted, and/or supplemented in various embodiments. Features, structures, materials, arrangements, and operations described in connection with one embodiment may be used with, combined with, substituted for, and/or adapted to other embodiments unless expressly stated otherwise. In many instances, well-known materials, fabrication techniques, resist-processing steps, optical components, alignment techniques, control techniques, and/or lithographic operations are not described in detail to avoid obscuring aspects of the disclosure.

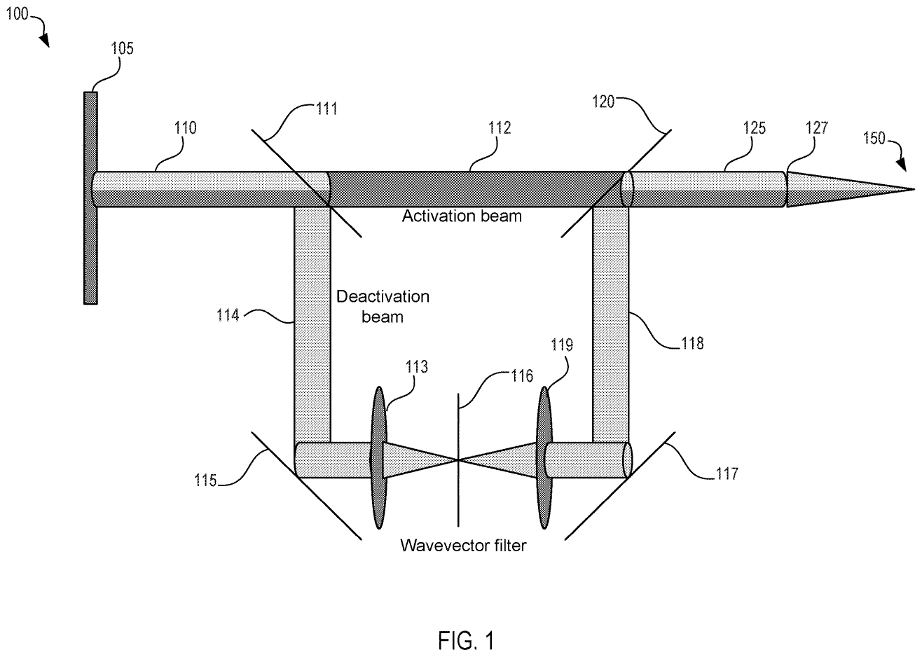

FIG. 1 illustrates a conceptual block diagram of a two-color projection lithography system 100. The system 100 includes a mask 105 that defines a pattern to be transferred to a photosensitive layer on a substrate. The system 100 is configured to receive first optical radiation at a first wavelength, which functions as an activation beam, and second optical radiation at a second wavelength, which functions as a deactivation beam. The mask 105 patterns the optical radiation at both wavelengths. The patterned fields are directed through projection optics so that the corresponding first- and second-patterned images are formed in registration at the target region 150. The target region 150 may correspond to a photoresist layer, wafer surface, or other substrate location at which the patterned images overlap.

In the illustrated embodiment, a first patterned field propagates from the mask 105 along an upper optical path that includes an input beam segment 110, a first upper-path segment 112, and an output beam segment 125. The upper optical path corresponds to an activation path in which the patterned optical field remains substantially unfiltered or is filtered differently from the deactivation path. A first wavelength-selective optical element 111 is positioned in the upper optical path. A second wavelength-selective optical element 120 is positioned downstream of the first wavelength-selective optical element 111. In various embodiments, the wavelength-selective optical elements 111 and 120 may be implemented as beam splitters, dichroic elements, mirrors, partially reflecting elements, wavelength-selective combiners, or other optical routing components configured to separate and later recombine the activation and deactivation optical fields. A downstream projection optic or objective element 127 (shown schematically) may receive the output beam segment 125 and image the overlapping patterned fields to the target region 150.

A portion of the patterned optical field is directed by the first wavelength-selective optical element 111 into a lower branch that defines a deactivation path. In the illustrated example, the deactivation path includes a first lower segment 114, a first lower optical directing element 115, relay optics 113 and 119, a wavevector filter 116, a second lower optical directing element 117, and a second lower segment 118. The lower branch receives a patterned optical field in the second wavelength (deactivation wavelength) derived from the mask 105 and processes that field so that the deactivation beam has a spatial intensity profile different from that of the activation beam (first wavelength). In some embodiments, the relay optics 113 and 119 define or relay an image plane, object plane, conjugate image plane, pupil plane, Fourier plane, or other pupil-associated plane at which one or more optical shaping operations can be performed.

In the illustrated embodiment, the wavevector filter 116 is disposed in the deactivation path and is configured to control which wave vectors propagate through the lower branch, thereby controlling the transfer function and point spread function associated with the deactivation beam. In some embodiments, the wavevector filter 116 is disposed behind the mask 105, adjacent to the mask 105, or at a plane optically conjugate to the mask 105. In some embodiments, the wavevector filter 116 may be implemented as a thin-film wavevector filter, an aperiodic thin-film filter, a periodic metasurface, or another optical filter having a wavevector-dependent transfer function. The wavevector filter 116 may implement a high-pass or a differentiating spatial filter. For example, the wavevector filter 116 may comprise a differentiating spatial filter that approximates a second-order spatial derivative, so that the deactivation image emphasizes edges of the pattern defined by the mask 105. In other embodiments, the wavevector filter 116 and/or another optical shaping element may produce a center-depleted, annular, donut-like, or otherwise depletion-like intensity profile that suppresses exposure around selected portions of the activation image.

After filtering and/or shaping, the deactivation beam returns through the second lower segment 118 to the second optical element 120. The second optical element 120 recombines the deactivation beam with the activation beam carried by the upper path, at 112. The recombined field then propagates along the output beam segment 125 toward the target region 150. In various embodiments, the activation beam forms an image corresponding substantially to the mask pattern itself, while the deactivation beam forms an outline, edge map, or other modified image derived from the same mask pattern. Superposition of the activation and deactivation images at the target region 150 suppresses exposure in selected regions, such as the edge regions of the activation image. The resulting exposure region is narrower than that produced by the activation image alone. Accordingly, the system 100 may form features whose smallest dimensions are below a diffraction-limited width, and thus smaller than could be achieved using a single-wavelength activation image alone.

In some embodiments, the lower branch shown between the wavelength-selective optical element 111 and the beam-directing element 120 represents a deactivation optical arm of a split-arm projection system, while the upper branch represents an activation optical arm. In some embodiments, one or more additional optical shaping elements may be provided in object space, image space, Fourier space, or both. For example, a spatial filter can be positioned at or near the mask 105 and/or at a plane optically conjugate to the mask 105. One or more additional phase-shaping and/or amplitude-shaping elements may be positioned at a pupil-associated plane, such as a pupil plane, Fourier plane, or aperture stop plane. In some embodiments, the system 100 includes shaping elements, such as a spiral phase plate, an apodizing intensity filter, or both. Any of these additional optical elements may be used separately or in combination with the wavevector filter 116 to tailor the deactivation point spread function, for example, to improve resolution, pitch fidelity, and/or feature density.

In some embodiments, the mask 105 is an amplitude-only mask. In other embodiments, the mask 105 is a phase-and-amplitude mask configured to modulate amplitude and phase at both the first wavelength and the second wavelength. The phase-and-amplitude distribution of the mask 105 may be co-optimized with the wavevector filter 116 and/or with any additional optical shaping elements in the system. The co-optimization may be implemented so that neighboring features of a dense pitch pattern remain sufficiently separated while the exposure width is reduced. In some embodiments, transmissive regions of the mask 105 have phase delays selected from values between 0 and 2π, including binary, ternary, or higher-order phase values. In some embodiments, approximately π phase differences may be introduced between adjacent transmissive regions to suppress interference fringes and/or improve printable pitch density. In some embodiments, the phase distribution is selected using modeling or inverse design. For example, the phase distribution and/or other characteristics of the mask 105 may be selected by optimizing an overlap metric or an intersection-over-union metric as a function of pitch.

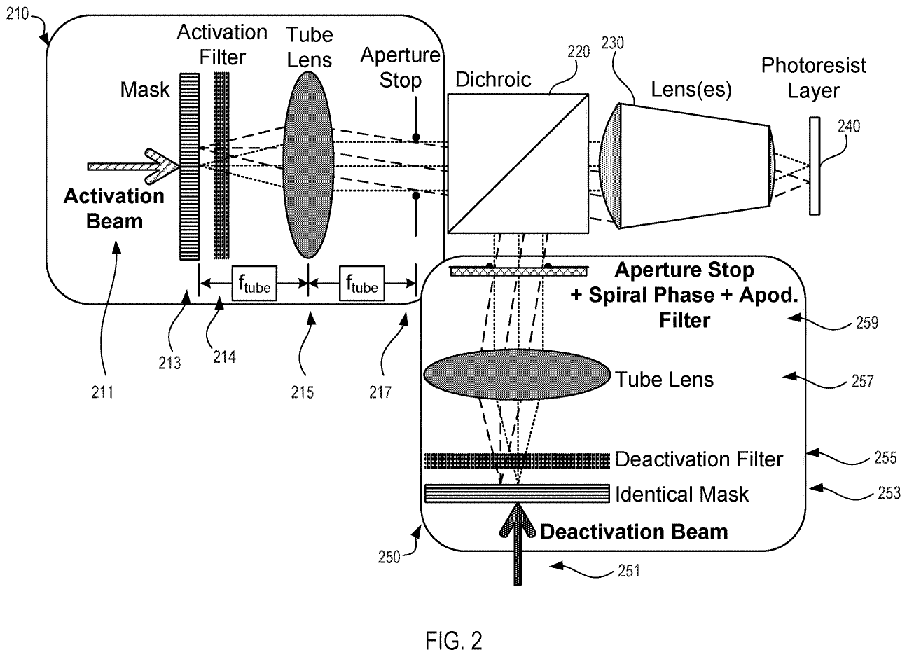

FIG. 2 illustrates one embodiment of a split-arm, two-color projection lithography architecture in which a first optical arm 210 carries an activation beam and a second optical arm 250 carries a deactivation beam. In the illustrated embodiment, the first optical arm 210 receives first optical radiation as an activation beam 211, and the second optical arm 250 receives second optical radiation as a deactivation beam 251. The activation beam 211 and the deactivation beam 251 are at different wavelengths and are processed in separate optical paths before being combined and projected to a photoresist layer 240. The illustrated embodiment is a projection system in which corresponding first and second patterned images are formed from the same pattern or from corresponding masks that define the same pattern. The first and second patterned images are brought into registration (e.g., aligned) and projected onto the photoresist layer 240 (e.g., on a substrate or wafer).

The first optical arm 210 includes a first mask 213 arranged to define a pattern for the activation beam 211. In the illustrated embodiment, the activation beam 211 is incident on the first mask 213 and then passes through an activation filter 214 shown adjacent the first mask 213. The activation filter 214 may be disposed behind the first mask 213, adjacent the first mask 213, or otherwise at or near an image plane of a respective tube lens 215. The activation filter 214 may comprise a wavevector filter, a thin-film filter, or another wavelength-selective or spatial-frequency-selective optical element. In some embodiments, the activation filter transmits the activation beam substantially unaugmented or unamplified. In other embodiments, the activation filter provides a transfer function selected for the first wavelength (e.g., different from the transfer function used in the deactivation arm 250). The first optical arm 210 further includes the respective tube lens 215 and an aperture stop 217 disposed at a pupil-associated plane of the tube lens 215. Examples of pupil-associated planes, as used herein, include a pupil plane, a Fourier plane, or an aperture stop plane. As suggested by the distances labeled “f_{tube},” the first mask 213 and the activation filter 214 may be positioned at an image plane of the tube lens 215. The aperture stop 217 may be positioned at the pupil plane of the tube lens 215.

The second optical arm 250 includes the deactivation beam 251, a second mask 253 identified in the figure as an “identical mask,” a deactivation filter 255, a respective tube lens 257, and a pupil-plane shaping arrangement 259. The second mask 253 may be physically separate from the first mask 213 while defining the same pattern as the first mask 213, thereby providing corresponding patterned optical fields in the activation and deactivation arms. In the illustrated embodiment, the deactivation beam 251 passes through the second mask 253 and then through the deactivation filter 255 before reaching the tube lens 257. The deactivation filter 255 may be disposed behind the second mask 253, adjacent the second mask 253, or at or near an image plane of the tube lens 257. The deactivation filter 255 may comprise a wavevector filter, such as a thin-film wavevector filter, a periodic metasurface, a multilayer thin-film filter, an inverse-designed filter, or another optical element with a wavevector-dependent transfer function. The deactivation filter 255 may be selected to modify the spatial-frequency content of the deactivation beam 251 so that the corresponding second patterned image has an edge-emphasizing, center-depleted, annular, donut-like, or otherwise deactivation-type spatial intensity profile.

The pupil-plane shaping arrangement 259 is disposed at a pupil-associated plane of the second optical arm 250. For example, the pupil-associated plane at which the pupil-plane shaping arrangement 259 is positioned may be at a pupil plane, a Fourier plane, or an aperture stop plane of the tube lens 257. In the illustrated embodiment, the arrangement 259 includes an aperture stop, a spiral phase element, and an apodizing intensity filter. The arrangement 259 may define a pupil-plane stack that limits allowed wave vectors in the second optical arm 250 and/or shapes the phase and/or amplitude of the deactivation beam 251. The aperture stop portion of the arrangement 259 may limit the wave vectors admitted into the deactivation optical train. In embodiments that include a spiral phase element and/or an apodizing intensity filter, these elements may also modify the point spread function and/or the amplitude transfer function of the deactivation path. In some embodiments, the arrangement 259 produces a point spread function with a center region that has a reduced intensity and an annular intensity distribution.

In various embodiments, the first optical arm 210 and the second optical arm 250 are optically combined by a dichroic element 220 or another optical combining element. The dichroic element 220 may comprise a dichroic beam splitter, wavelength-selective combiner, partially reflecting optical coupler, or other combining element configured to receive patterned radiation from the first optical arm 210 and the second optical arm 250 and to direct the combined beams toward shared projection optics. In the illustrated embodiment, the shared projection optics include one or more lenses 230 positioned downstream of the dichroic element 220. The one or more lenses 230 may function as projection optics, an objective lens group, relay optics, or any combination thereof. The one or more lenses 230 may be configured to image the combined patterned beams onto the photoresist layer 240. The photoresist layer 240 may be disposed on a substrate, wafer, or other workpiece. The term photoresist layer is used herein in a broad sense that encompasses any of a wide variety of one or more radiation-responsive layer(s).

The first optical arm 210 forms a first patterned image at the first wavelength, and the second optical arm 250 forms a second patterned image at the second wavelength. Because the first mask 213 and the second mask 253 correspond to the same pattern, the first and second patterned images are derived from a common pattern and are brought into spatial registration at the photoresist layer 240 by the shared projection optics. The first patterned image may correspond substantially to the nominal mask pattern, while the second patterned image may be modified by the deactivation filter 255 and the pupil-plane shaping arrangement 259 to have a different spatial intensity profile. Superposition of the first and second patterned images at the photoresist layer 240 can leave an exposed region that is narrower than that produced by the first patterned image alone, thereby enabling sub-diffraction-limited feature formation and/or improved pitch pattern fidelity (including pattern density).

In some embodiments, the first mask 213 and the second mask 253 may be separate masks fabricated independently but defining the same pattern, or may be formed as corresponding patterned regions in different arms of a system. The activation filter 214 and deactivation filter 255 may have identical or different transfer functions. The pupil-plane shaping arrangement 259 may be implemented as separate stacked elements or as an integrated optical element. The dichroic element 220 may be replaced with another wavelength-selective combiner, and the one or more lenses 230 may comprise one lens, multiple lenses, relay optics, an objective lens group, or infinity-corrected projection optics. In some embodiments, the system may further include an alignment subsystem with electronic and/or mechanical components to maintain registration of the first and second patterned images.

In some embodiments, the first mask 213 and/or the second mask 253 may be phase-and-amplitude masks rather than amplitude-only masks. In such embodiments, the phase and amplitude distributions of the masks may be co-optimized with the transfer function of the deactivation filter 255 and/or with the pupil-plane shaping arrangement 259 so that neighboring features of a dense-pitch pattern remain sufficiently separated while the deactivation image suppresses exposure outside a desired patterning area. In some embodiments, transmissive regions of the masks may have phase delays selected from values between 0 and 2π, including binary, ternary, or higher-order phase values. In some embodiments, approximately π phase differences may be introduced between adjacent transmissive regions to suppress interference fringes and/or improve printable pitch density. In some embodiments, the phase distribution may be selected using modeling or inverse design.

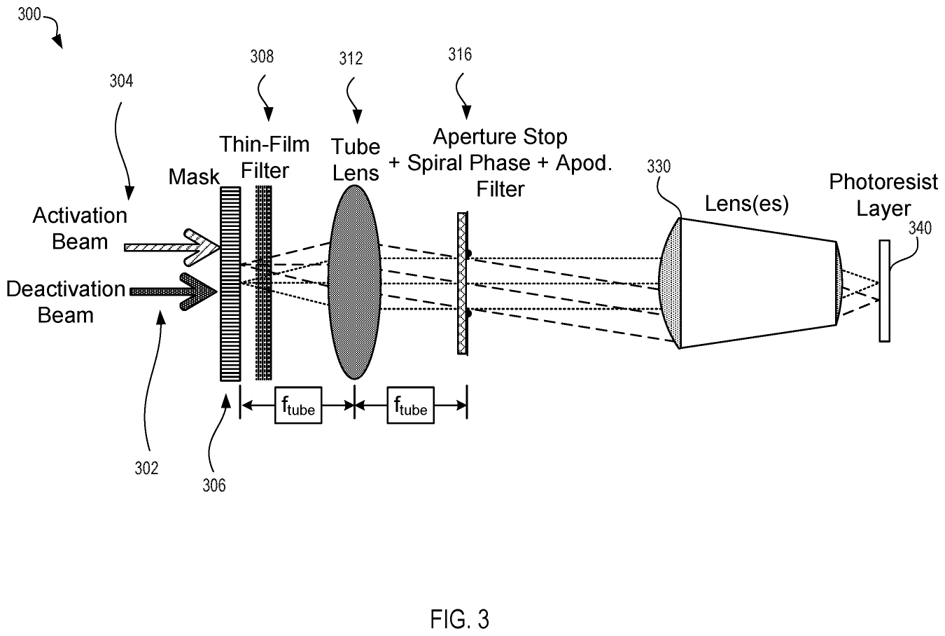

FIG. 3 illustrates one embodiment of a common-path, two-color projection lithography architecture 300. In the illustrated embodiment, an activation beam 304 and a deactivation beam 302 are directed into a shared optical train so that first optical radiation at a first wavelength and second optical radiation at a second wavelength co-propagate through substantially the same patterning and projection optics. The shared optical train includes a mask 306, a thin-film filter 308, a tube lens 312, a pupil-associated shaping plane 316, one or more downstream projection lenses 330, and a photoresist layer 340. In operation, the common optical train forms a first patterned image and a second patterned image from the same mask-defined pattern and projects those patterned images in registration to the photoresist layer 340.

The mask 306 defines a pattern to be transferred to the photoresist layer 340. In some embodiments, the mask 306 is an amplitude mask. In other embodiments, the mask 306 is a phase-and-amplitude mask configured to modulate both amplitude and phase at both the first and second wavelengths. The activation beam 304 and the deactivation beam 302 are both incident on the mask 306 so that each beam is patterned by the same mask features. The thin-film filter 308 is disposed in the common optical train and receives the patterned optical field produced by the mask 306. In some embodiments, the thin-film filter 308 comprises a wavelength-selective and wavevector-selective optical element having a first transfer function at the first wavelength and a second transfer function at the second wavelength. For example, the thin-film filter 308 may transmit the activation beam 304 substantially without augmentation while spatially filtering the deactivation beam 302. That is, the thin-film filter 308 may alter the spatial-frequency content of the second wavelength-patterned optical field. The thin-film filter 308 may function as a common filter element for both wavelengths while affecting the deactivation beam differently from the activation beam.

In some embodiments, the thin-film filter 308 is a thin-film wavevector filter, such as an aperiodic thin-film filter (e.g., with multiple layers), a multilayer thin-film filter, an inverse-designed thin-film filter, or another filter having a wavevector-dependent transfer function. The thin-film filter 308 may be configured to implement a high-pass, differentiating, or other spatial filtering operation that produces an edge-emphasizing or depletion-type response for the second patterned image. The filter 308 may be located at, behind, adjacent to, or at a plate optically conjugate to the mask 306. The tube lens 312 may relay the patterned optical field from the mask 306 to a pupil plane, Fourier plane, or aperture-stop plane, at 316.

The shaping plane 316 may include an aperture stop, a spiral phase element, and/or an apodizing intensity filter arranged at a pupil-associated plane of the common optical train. In some embodiments, these structures are formed as separate stacked optical components. In other embodiments, two or more of these functions are integrated into a single optical shaping element. The aperture stop at plane 316 may limit the allowed wave vectors that continue through the common optical train. The spiral phase element may impart phase shaping that produces a point spread function with a center region of reduced intensity and/or an annular intensity distribution. The apodizing intensity filter may impose amplitude shaping that adjusts the radial intensity distribution and suppresses undesired sidelobes or tails.

In some embodiments, the optical structures at plane 316 cooperate with the thin-film filter 308 to shape the second optical radiation while leaving the first optical radiation unmodified or differently modified. For example, the thin-film filter 308 and the shaping plane 316 may together define a first wavelength response for the activation beam 304 and a second wavelength response for the deactivation beam 302. The first wavelength response may preserve the first patterned image substantially as defined by the mask 306, while the second wavelength response may produce a deactivation image having an edge-emphasizing, center-depleted, ring-shaped, or otherwise modified spatial intensity profile. In the photoresist layer 340, the first and second patterned images overlap and cooperate, resulting in a narrower exposure region than would be produced by the first patterned image alone. In some embodiments, the deactivation image suppresses exposure at edge regions of the activation image, thereby enabling sub-diffraction-limited linewidths or improved dense-pitch feature fidelity.

Downstream of the shaping plane 316, the shared patterned radiation is directed through one or more lenses 330. The one or more lenses 330 may comprise projection optics, relay optics, an objective lens group, or another imaging arrangement configured to project the patterned optical field onto the photoresist layer 340. In the illustrated embodiment, both wavelengths travel through the common optical train. The common or shared optical path can, in some instances, reduce relative alignment error between the first and second patterned images, as compared with some split-arm arrangements.

In various embodiments, the thin-film filter 308 may be replaced or supplemented by another wavevector filter, a wavelength-selective filter, a metasurface, or an inverse-designed optical element. Likewise, the shaping functions at plane 316 may be implemented by separate optical elements, an integrated optical stack, or a single common wavelength-selective element having different responses at the first and second wavelengths. The one or more lenses 330 may comprise one lens or multiple lenses, and the photoresist layer 340 may be any photosensitive layer responsive to the patterned radiation.

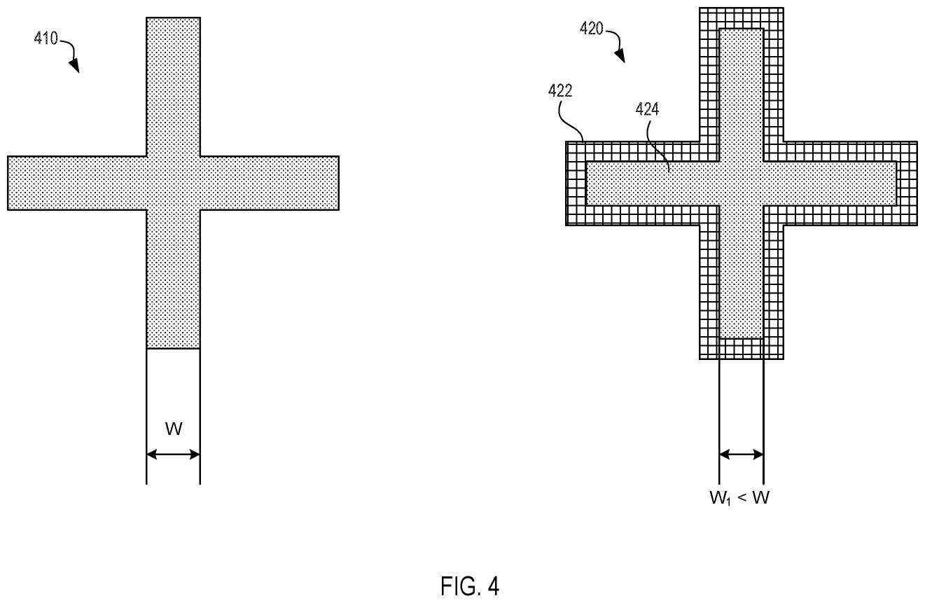

FIG. 4 illustrates, in a simplified schematic manner, a comparison between an example exposure profile 410 produced by projection of a first patterned image alone and an example two-color exposure profile 420 produced by superimposed projections of the first patterned image and a second patterned image. The illustrated shapes are shown as cross-shaped features for convenience, but the same principles apply to lines, spaces, contact openings, isolated features, dense-pitch features, periodic features, two-dimensional patterns, or other lithographic geometries.

The example profile 410 represents a patterned exposure or printed feature obtained from a single-color projection process, or from the projection of an activation image without a corresponding deactivation image. In the illustrated embodiment, the profile 410 has a representative feature width, W. The width, W, may correspond to a linewidth, critical dimension, exposure width, or other transverse dimension associated with a feature produced by the first patterned image alone. The example profile 420 schematically represents a two-color result in which a first patterned image and a second patterned image derived from the same mask pattern are projected in registration and superposed at a photosensitive layer. In the illustrated embodiment, the profile 420 includes an outer region 422 and an inner region 424. The outer region 422 may represent a deactivation field, a suppression region, an edge-emphasizing region, or another portion of the second patterned image that overlaps edge portions of the first patterned image. The inner region 424 may represent a remaining exposure region or an effective exposure region produced after the second patterned image suppresses exposure around the edges of the first patterned image.

As shown in FIG. 4, the inner region 424 has a representative feature width, W₁, that is less than the width, W, of the profile 410. Thus, the combined two-color exposure profile 420 leaves a narrower exposure region than the activation-only or single-color profile 410. In various embodiments, this narrowing results from spatial overlap between the first and second patterned images, with the second patterned image reducing effective exposure in regions adjacent to the edges of the first patterned image. The deactivation action may be produced by wavevector-dependent filtering, phase shaping, amplitude shaping, or a combination thereof, as described according to any combination of the embodiments herein.

Notably, the outer region 422 is shown surrounding the inner region 424 along all sidewall or edge portions of the cross-shaped feature. In various embodiments, the outer region 422 corresponds to an edge-emphasizing intensity profile derived from the same mask pattern as the first patterned image. In some embodiments, the outer region 422 corresponds to a center-depleted, annular, donut-like, or otherwise depletion-type intensity profile that overlaps the first patterned image, thereby narrowing the resulting exposure region. In the example shown, both the single-color profile 410 and the two-color profile 420 retain a cross-shaped configuration, but the inner region 424 of the two-color profile 420 is narrower than the corresponding feature in profile 410. This demonstrates that the disclosed systems and methods can preserve pattern identity while reducing feature size.

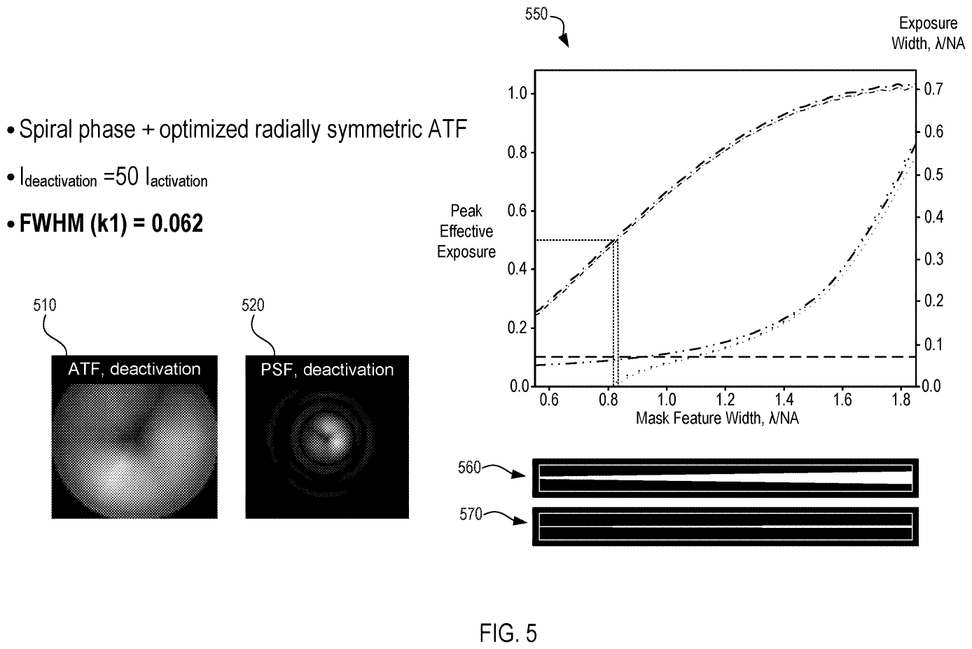

FIG. 5 illustrates one non-limiting example of design parameters and performance characteristics for a two-color projection lithography system in which a deactivation optical path is shaped by a spiral phase element and an optimized radially symmetric amplitude transfer function (ATF). The illustration includes a deactivation ATF representation 510, a deactivation point spread function (PSF) representation 520, a performance plot 550, and schematic feature representations 560 and 570. The annotations in FIG. 5 identify one example operating regime in which the deactivation path employs a spiral phase together with an optimized radially symmetric ATF. In the specific non-limiting example, the deactivation beam intensity is about 50 times that of the activation beam. In the illustrated example, the system attains a full width at half maximum (FWHM) corresponding to a lithography resolution pre-factor k1 of about 0.062.

Various modifications to the deactivation-path transfer function, deactivation-path PSF design, and/or relative activation/deactivation intensities may be selected to achieve a target exposure width in a projection-based two-color lithography system. The deactivation ATF representation 510 schematically depicts an example amplitude transfer function for the deactivation optical path. As used herein, the amplitude transfer function (ATF) characterizes how amplitude associated with spatial-frequency components, or wave-vector components, of the deactivation optical field is transmitted through the deactivation optical system. In some embodiments, the deactivation ATF is selected to be radially symmetric in the pupil or Fourier domain. In such embodiments, the magnitude of the transfer function depends on the radial distance from the optical axis. In the illustrated embodiment, the deactivation optical path includes both a spiral phase contribution and an optimized radially symmetric amplitude contribution. The spiral phase contribution may impart an azimuthally varying phase profile, while the ATF controls the magnitude response across spatial frequencies. In various embodiments, the ATF represented by 510 may be implemented by one or more optical shaping elements disposed at a pupil-associated plane, such as a pupil plane, Fourier plane, or aperture stop plane.

The deactivation PSF representation 520 schematically depicts a corresponding point spread function for the deactivation optical path produced by the transfer-function design represented by 510. In the illustrated example, the PSF 520 is a center-depleted ring, which may also be described as annular, donut-like, or depletion-like. In various embodiments, the deactivation PSF 520 may be produced by cooperation between a spiral phase element and a radially selected amplitude profile. The resulting deactivation image suppresses exposure at selected regions of an activation image while leaving a narrower central exposure region. In some embodiments, the PSF 520 corresponds to a deactivation image that overlaps edge regions of an activation image of the same mask pattern. In other embodiments, the PSF 520 is selected to reduce exposure in a more generalized outer region around a target feature to sharpen a printed feature.

The performance plot 550 relates feature-size and exposure-response quantities for one example system configuration. In the illustrated embodiment, the horizontal axis expresses feature width in normalized units based on wavelength and numerical aperture. The first vertical axis shows the peak effective exposure, and the second vertical axis shows the exposure width in terms of wavelength and numerical aperture. The system may be customized to implement specific ATF and PSF responses and/or various relative activation/deactivation intensities to achieve a target exposure level and exposure width, as a function of the width of a corresponding mask feature. FIG. 5 shows one particular set of curves; however, the curve shapes and specific numerical values are merely one example and are not intended to be limiting. Other embodiments may use different transfer functions, wavelengths, numerical apertures, intensity ratios, photoresists, or optimization criteria. In the illustrated example, the second optical radiation has a greater intensity than the first at the photosensitive layer, specifically, the intensity ratio is about 50:1. In various embodiments, the intensity ratio of the second optical radiation to the first optical radiation may be selected as part of an optimization process.

The schematic feature representations 560 and 570 provide a visual comparison between a feature associated with a mask-defined width and a corresponding narrower exposure produced by the disclosed two-color shaping scheme. In the illustrated embodiment, the upper schematic 560 may represent an example mask feature, line, space, or nominal patterned opening having a selected width in normalized units (the “selected width” may be diffraction-limited). The lower schematic 570 may represent a corresponding effective exposure width or printed width after superposition of the activation image and the shaped deactivation image. The difference between 560 and 570 visually reinforces that the final exposure width can be narrower than the corresponding feature width defined at the mask (which may be diffraction-limited).

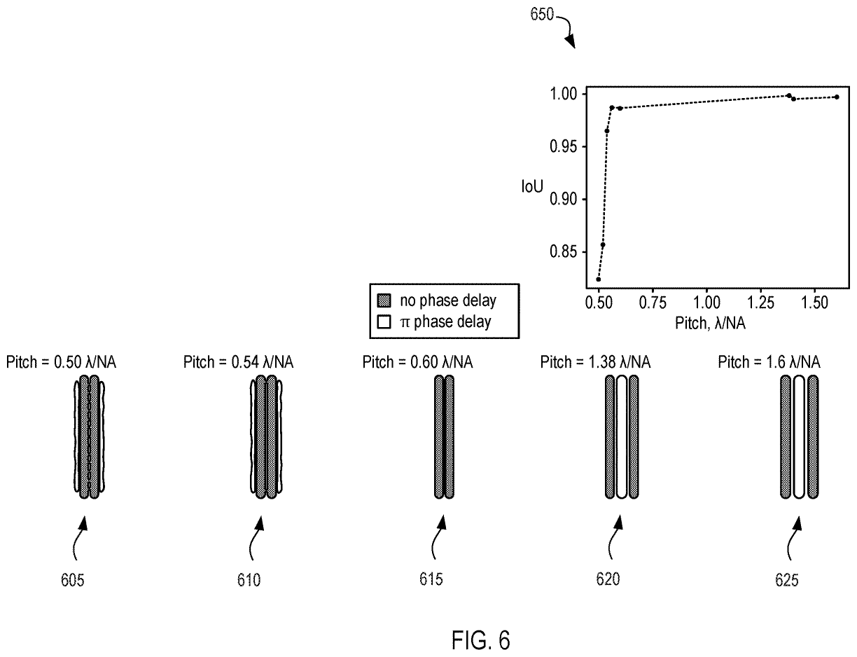

FIG. 6 illustrates one example of a phase-delay and pitch-density analysis 605 for a two-color projection lithography system. In the illustrated embodiment, FIG. 6 includes a set of representative phase-mask comparison panels 610, 615, 620, and 625 and a fidelity plot 650 for a pattern. The comparison panels are labeled with example normalized feature pitches, including 0.50 λ/NA, 0.54 λ/NA, 0.60 λ/NA, 1.38 λ/NA, and 1.6 λ/NA, where λ denotes the deactivation wavelength, and NA is the numerical aperture of the projection optics. The figure also distinguishes between cases with no phase delay and those with a phase delay of π. As described herein, mask phase selection can affect the pitch-density performance in a projection-format two-color lithography system.

The representative panels 610, 615, 620, and 625 schematically depict example pattern feature arrangements at different pitches under different mask phase conditions. In one set of examples, adjacent transmissive regions corresponding to adjacent patterned features are provided with no intentional phase delay. In another set of examples, adjacent transmissive regions are provided with a relative phase delay of about π (alternative phase delays between 0 and 2π may be used during the optimization process). The phase relationship between neighboring mask features can materially affect whether neighboring printed or exposed features remain distinct, merge, blur, or otherwise lose fidelity as pitch decreases.

In various embodiments, the no phase delay examples (shown in white) correspond to mask regions in which adjacent transmissive regions have substantially the same phase. The π phase delay examples correspond to mask regions in which at least some adjacent transmissive regions have opposite phase or a relative phase offset. The phase offset can suppress or reshape interference between adjacent projected features, thereby improving feature contrast and permitting neighboring features to be placed closer together without washing out the target pattern.

Pitch density is a distinct design issue separate from the design issue of narrowing isolated feature widths. In a projection system, many features of a mask are imaged simultaneously, so neighboring patterned entities have the potential to overlap or interfere with one another. Optimizing the mask phase distribution and/or optical filtering can reduce or eliminate interference. For example, specific phase delays on the mask may be implemented to reduce interference fringes that might otherwise blur the intended image.

The pattern-fidelity plot 650 provides a quantitative example of this behavior. In the illustrated embodiment, the horizontal axis of plot 650 shows the pitch, and the vertical axis shows a corresponding intersection-over-union metric (alternative overlap-quality metrics may be used). The intersection-over-union metric compares a resulting exposure pattern, aerial image, or printed feature with a target pattern. Higher intersection-over-union values correspond to closer agreement between the produced pattern and the target pattern, while lower intersection-over-union values correspond to greater distortion, overlap, washout, or other loss of fidelity. The phase distribution for a given mask, filter, and/or other optical elements may be determined by modeling, simulation, or inverse design. The phase layout across a mask that yields the highest fidelity may not be intuitive on a feature-by-feature basis, nor may it be readily calculable using an algorithm or equation. However, for a given mask, the phase layout can be determined using full- or partial-system inverse-design and/or other modeling approaches.

Accordingly, in various embodiments, the systems, methods, and masks described herein utilize a combined phase-and-amplitude optimization process, in which the phase and amplitude values are optimized simultaneously for both the activation and deactivation projections. In embodiments in which the beam paths for the activation and deactivation wavelengths are shared, a single mask may be co-optimized for both wavelengths, simultaneously optimizing phase and amplitude. In two-arm or other split-beam embodiments, separate masks may be co-optimized. Furthermore, the mask phase arrangement may be co-optimized with filters in the object and/or image space and/or in the Fourier and/or pupil space.

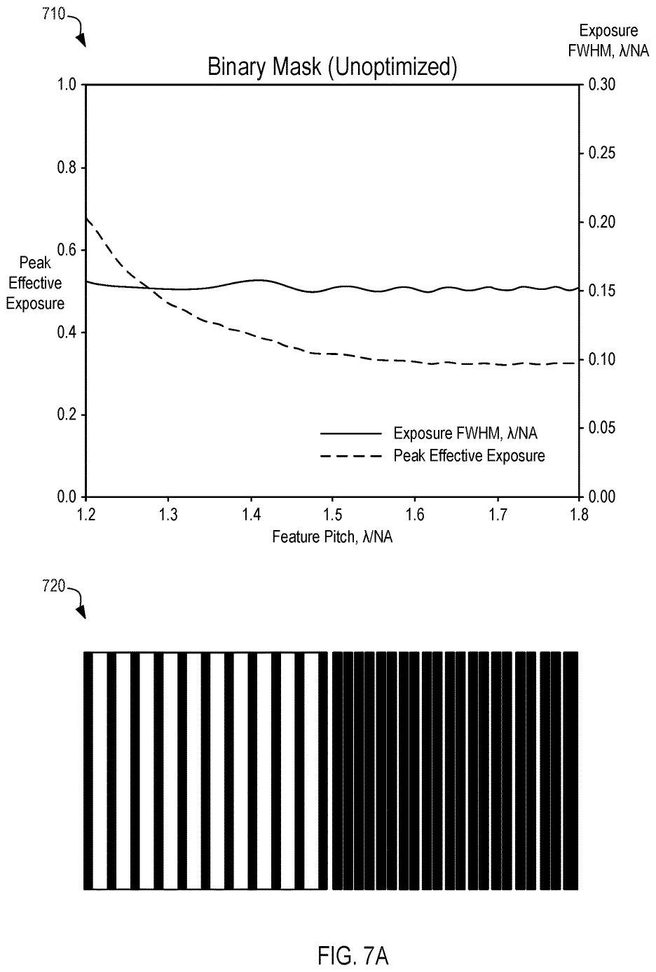

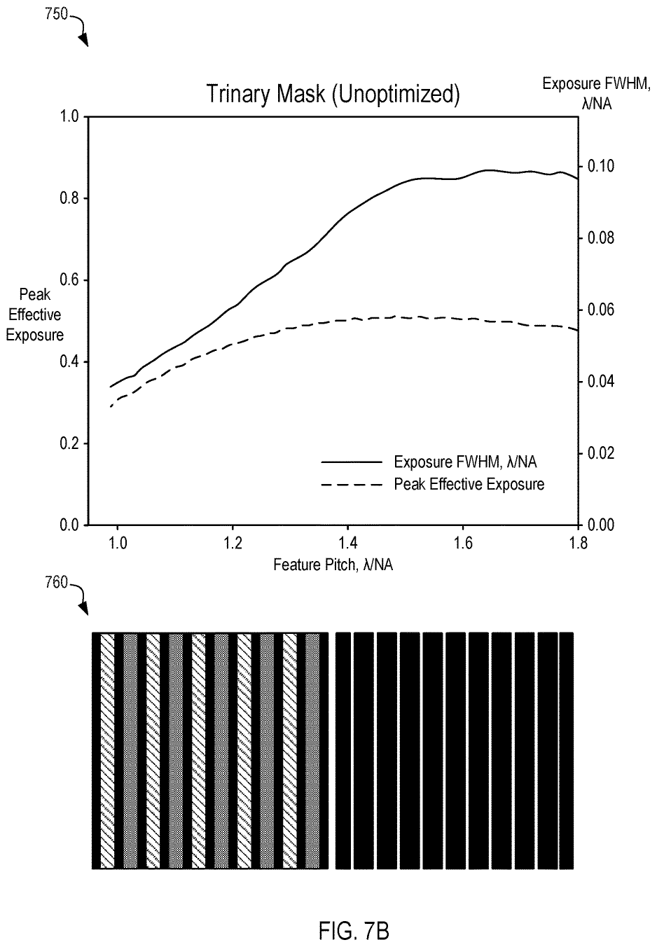

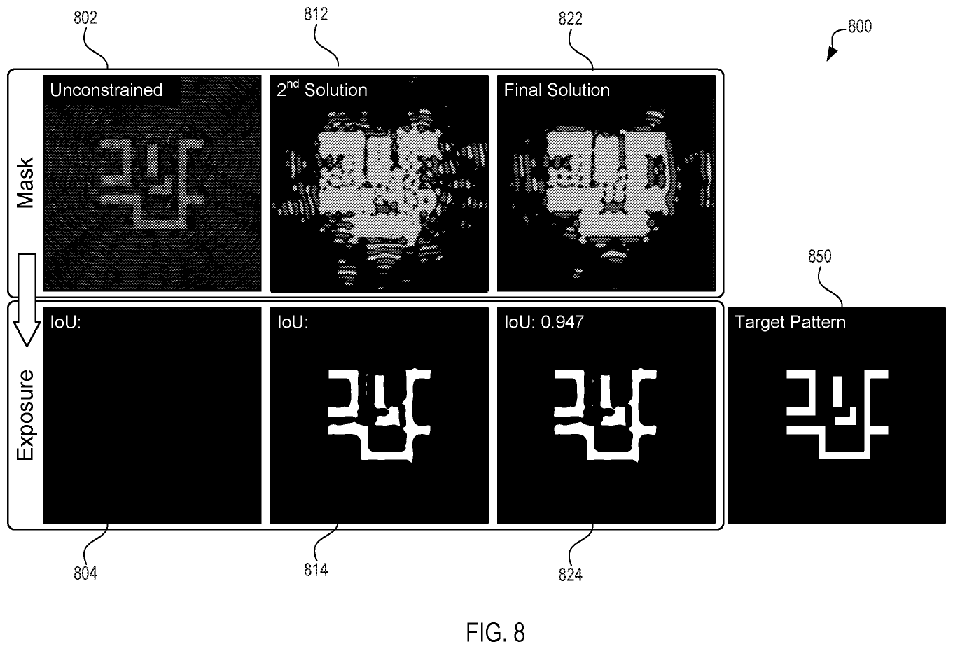

FIGS. 7A and 7B illustrate comparative examples of pitch-dependent performance for unoptimized masks that have various numbers of available mask states. FIG. 8 illustrates one example of an inverse design workflow and corresponding mask and exposure solutions for a selected target pattern. Collectively, these figures show that mask design in various embodiments of the disclosed two-color projection lithography systems is not limited to choosing a spatial filter or shaping element alone. To the contrary, the process may also include selecting, optimizing, and co-optimizing the phase-and-amplitude distribution of the mask itself.

FIG. 7A illustrates one example of a binary mask analysis 710 together with a corresponding schematic binary mask 720. In the illustrated embodiment, the dashed curve corresponds to peak effective exposure, and the solid curve corresponds to exposure FWHM. The schematic binary mask 720 shown beneath the plot may represent a binary phase mask, a binary amplitude mask, a binary phase-and-amplitude mask, or another binary lithographic mask having two available mask states. In some embodiments, the two states correspond to transmissive and blocking. In other embodiments, the two states correspond to first and second phase states. As shown in the plot 710, the peak effective exposure and the exposure FWHM vary with feature pitch in the unoptimized mask.

FIG. 7B illustrates one example of a trinary mask analysis 750 together with a corresponding schematic trinary mask 760. The dashed curve again corresponds to peak effective exposure, and the solid curve corresponds to exposure FWHM. The trinary mask 760 shown beneath the plot includes three visually distinct mask states and may represent, for example, a mask having three phase states, three amplitude states, or combined phase-and-amplitude states. In some embodiments, the trinary mask 760 may include phase features selected from values between 0 and 2. In other embodiments, the three states may correspond to different transmissivities, different phase delays, or different combinations of transmissivity and phase delay.

Comparison of FIG. 7A and FIG. 7B shows that increasing the number of available mask states changes the pitch-dependent behavior of peak effective exposure and exposure FWHM, even in unoptimized masks. As illustrated, simply selecting a binary mask or a trinary mask may not, by itself, provide a fully optimized design solution. Nevertheless, in some embodiments, suitable or adequate binary, ternary, or other higher-order masks may be utilized in some applications without full optimization. In other embodiments, the phase-and-amplitude distribution of the mask may be selected via an optimization process (e.g., inverse-design).

FIG. 8 illustrates one example of an inverse-designed mask/exposure comparison 800 for a selected target pattern 850. The illustrated example includes a matrix with an upper row of masks and a lower row of exposures. The directional arrow between the rows indicates that the mask solutions on the upper row are used to produce the exposure results on the lower row. The first column shows an unconstrained mask solution 802 and a corresponding exposure result 804. The second column shows an intermediate or second solution mask 812 and a corresponding exposure result 814. The third column shows a final solution mask 822 and a corresponding exposure result 824. The target pattern 850 is shown separately to the right for comparison with the exposure results.

The mask distribution resulting from the optimization process may not directly resemble the nominal target pattern 850. Rather, the solutions in the upper row may appear non-intuitive, spatially varying, or highly structured because they are selected to work with the projection optics and optical shaping elements to produce the desired exposure after optical propagation. In the illustrated example, the unconstrained solution 802 produces little or no useful exposure result in panel 804. The intermediate solution 812 produces an improved but still imperfect exposure result 814. The final solution 822 produces a final exposure result 824 that more closely matches the target pattern 850, with an intersection-over-union metric (IoU) value of 0.947.

The intersection-over-union metric represents any of a wide variety of overlap-quality metrics, fidelity metrics, cost-function values, or other optimization objectives used during the inverse mask design. As previously described, the mask optimization process may include simultaneous phase and amplitude optimization for both the activation and deactivation projections. Accordingly, the mask solutions 802, 812, and 822 may be understood as solutions that are not selected in isolation, but rather in view of the transfer function, point spread function, and other optical characteristics of the projection system. In some embodiments, the optimization process may be additionally constrained by pitch density considerations. For example, the mask phase-and-amplitude distribution may be selected so that neighboring features remain sufficiently separated at dense pitch and/or interference fringes are suppressed.

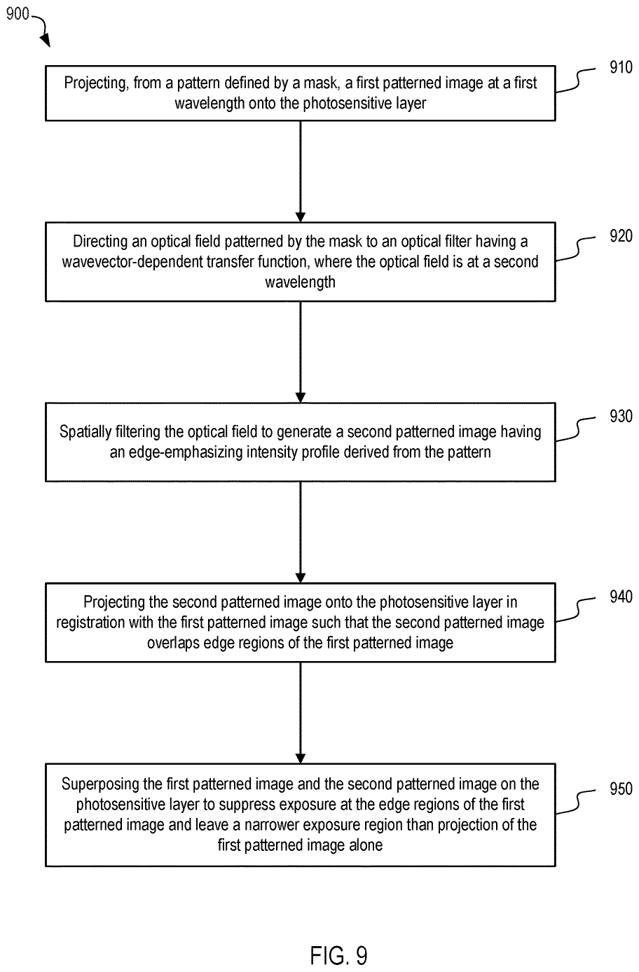

FIG. 9 illustrates one embodiment of a method 900 of forming a feature in a photosensitive layer using two-color projection lithography. The method 900 corresponds to any of the various embodiments described herein in which a first patterned image at a first wavelength is combined with a second patterned image at a second wavelength. In some embodiments, the deactivation pattern is derived from the same mask pattern and spatially filtered to provide an edge-emphasizing or depletion-like response. Although the illustrated boxes are shown in one order, the steps of method 900 may be performed in other orders, combined, omitted, repeated, or supplemented with additional operations.

At 910, the system may project, from a pattern defined by a mask, a first patterned image at a first wavelength onto the photosensitive layer. For example, the system may illuminate a mask defining a pattern with first optical radiation and use projection optics to form a first patterned image of the mask pattern on a photoresist layer. In some embodiments, the first patterned image may be an activation image. In some embodiments, the first patterned image may correspond substantially to a nominal image of the mask pattern.

At 920, the system may direct an optical field at a second wavelength, also patterned by the mask, to an optical filter with a wavevector-dependent transfer function. For example, after the second optical radiation is patterned by the mask, the system may direct the second-wavelength optical field to an optical filter disposed behind the mask, adjacent to the mask, or at a plane optically conjugate to the mask. In some embodiments, the optical filter may comprise a wavevector filter, a thin-film filter, an aperiodic thin-film filter (e.g., with multiple layers), a multilayer filter, a periodic metasurface, or another optical element having a wavevector-dependent transfer function.

At 930, the system may spatially filter the optical field to generate a second patterned image having an edge-emphasizing intensity profile derived from the pattern. For example, the optical filter may modify the spatial-frequency content of the second-wavelength optical field so that the resulting second patterned image emphasizes edges of mask features (e.g., to suppress low spatial frequencies and/or approximate a second-order spatial derivative of the pattern). In some embodiments, the second patterned image may exhibit a double-hump intensity distribution across an edge of a mask feature. In some embodiments, the filtered second-wavelength optical field may define a deactivation image derived from the same mask pattern as the first patterned image.

At 940, the system may project the second patterned image onto the photosensitive layer in registration with the first patterned image such that the second patterned image overlaps edge regions of the first patterned image. For example, the system may use a second optical train, or a portion of a common optical train, to project the second patterned image in registration with the first patterned image. That is, the first and second patterned images may be aligned on the photosensitive layer. In some embodiments, the system may maintain the first and second patterned images in registration using one or more alignment operations.

At 950, the system may superpose the first and second patterned images on the photosensitive layer to suppress exposure in the edge regions of the first patterned image. As described herein, this leaves a narrower exposure region than the projection of the first patterned image alone. The second patterned image may act as a deactivation image that suppresses exposure at edge regions of the first patterned image so that a remaining exposure region has a smaller width or critical dimension than would be produced by the first patterned image alone. In some embodiments, the resulting feature may have a critical dimension below a diffraction-limited critical dimension obtainable from the first patterned image alone.

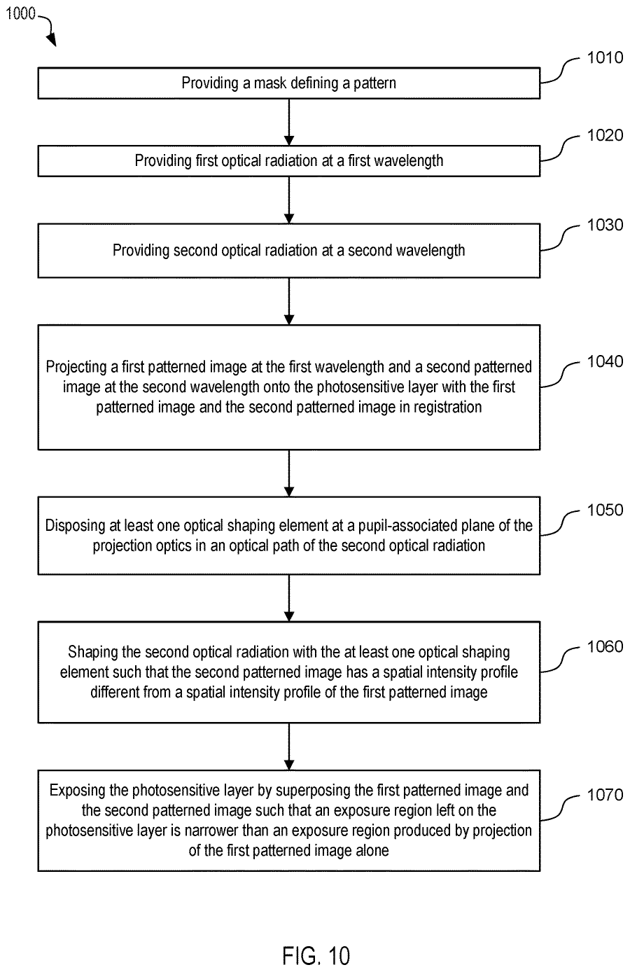

FIG. 10 illustrates one embodiment of a method 1000 of forming a feature in a photosensitive layer according to various embodiments in which at least one optical shaping element is disposed at a pupil-associated plane of the projection optics. Specifically, the method 1000 corresponds to embodiments in which the second optical radiation is shaped at a pupil plane, a Fourier plane, an aperture stop plane, or another pupil-associated plane, so that the second patterned image has a spatial intensity profile different from that of the first patterned image. Although the illustrated boxes are shown in one order, the steps of method 1000 may be performed in other orders, combined, omitted, repeated, or supplemented with additional operations.

At 1010, the system may provide a mask defining a pattern. For example, the system may provide a lithographic mask that defines a target pattern to be transferred to a photosensitive layer. In some embodiments, the mask may be an amplitude mask. In some embodiments, the mask may be a phase-and-amplitude mask configured to modulate amplitude and phase at both a first wavelength and a second wavelength. In some embodiments, the mask may include binary phase features, ternary phase features, or higher-order phase features, and transmissive regions of the mask may have various phase delays.

At 1020, the system may provide the first optical radiation at a first wavelength. For example, the system may generate, deliver, convey, reflect, refract, and/or otherwise provide first optical radiation to an activation optical path of the projection lithography system. In some embodiments, the first optical radiation may form a first patterned image corresponding substantially to the nominal mask pattern. At 1030, the system may provide the second optical radiation at a second wavelength, where the second wavelength differs from the first wavelength. In some embodiments, the second optical radiation may be selected to cooperate with the first optical radiation so that, after shaping and projection, the resulting second patterned image narrows an exposure region produced by the first patterned image. That is, the first optical radiation may be considered the activation beam, while the second optical radiation may be considered the deactivation beam, or vice versa for an inverted mask.

At 1040, the system may project a first patterned image at the first wavelength and a second patterned image at the second wavelength onto the photosensitive layer. The first and second patterned images may be registered (e.g., aligned with respect to each other or with respect to another alignment reference). In some embodiments, the system may use separate optical arms that are combined upstream of a common objective, or may use a common optical train through which the first and second optical radiation co-propagate. In some embodiments, the first and second patterned images may be derived from the same mask. In other embodiments, the first and second patterned images may be derived from separate masks defining the same pattern.

At 1050, the system may include at least one optical shaping element at a pupil-associated plane of the projection optics in an optical path of the second optical radiation. For example, the system may position one or more optical shaping elements at a pupil plane, a Fourier plane, or an aperture stop plane of the projection optics. In some embodiments, the at least one optical shaping element may comprise an aperture stop, a spiral phase plate, an apodizing intensity filter, and/or a combination thereof. For example, a pupil-plane stack may include both a spiral phase plate and an apodizing intensity filter. In some embodiments, one or more optical shaping elements may be disposed in a deactivation optical arm. In other embodiments, one or more optical shaping elements may be in a shared optical train and may have different responses at the first and second wavelengths.

At 1060, the system may shape the second optical radiation with at least one optical shaping element so that the second patterned image has a spatial intensity profile different from that of the first patterned image. For example, the system may shape the second optical radiation by phase shaping, amplitude shaping, wavevector-dependent filtering, or a combination thereof. In some embodiments, the at least one optical shaping element may implement an optimized amplitude transfer function, such as an optimized radially symmetric amplitude transfer function, for the second optical radiation. In some embodiments, the shaping may produce a target point spread function that is center-depleted, annular, ring-shaped, donut-like, edge-emphasizing, or otherwise selected to suppress exposure outside a target feature region. In some embodiments, the second optical radiation may be shaped in cooperation with an additional wavevector filter located at the mask, adjacent to the mask, or at a plane optically conjugate to the mask.

At 1070, the system may expose the photosensitive layer by superposing the first and second patterned images, so that the exposure region on the photosensitive layer is narrower than that produced by the projection of the first patterned image alone. For example, the system may use the shaped second patterned image to suppress exposure in outer regions, edge regions, or neighboring regions of the first patterned image. The remaining exposure region may therefore have a reduced width, reduced full width at half maximum, reduced critical dimension, and/or improved pitch fidelity. In some embodiments, the first optical radiation and the second optical radiation may be provided at relative intensities selected to obtain a target feature width, target FWHM, or target lithographic resolution (e.g., a target pre-factor k1 value).

The features, structures, and operations associated with one embodiment may be applied to or combined with the features, structures, or operations described in conjunction with another embodiment. In many instances, well-known structures, materials, or operations are not shown or described in detail to avoid obscuring aspects of this disclosure. The right to add any described embodiment or feature to any one of the figures and/or as a new figure is explicitly reserved.

The embodiments of the systems and methods provided within this disclosure are not intended to limit the scope of the disclosure but are merely representative of possible embodiments. In addition, the steps of a method, modeling, or simulation approach need not be executed. If the steps of a method, modeling, or simulation approach are executed, they need not be executed in any specific order, or even sequentially, nor do they need to be executed only once. In some instances, well-known structures, materials, or operations are not shown or described in detail to avoid obscuring aspects of this disclosure. This disclosure is to be regarded in an illustrative rather than a restrictive sense and includes and encompasses all compatible combinations of the following clauses and claims.

Clause 1. A projection lithography system for forming a feature in a photosensitive layer on a substrate, comprising: a mask defining a pattern; a first radiation source configured to provide first optical radiation at a first wavelength; a second radiation source configured to provide second optical radiation at a second wavelength different from the first wavelength; projection optics configured to project, from the pattern defined by the mask, a first patterned image at the first wavelength and a second patterned image at the second wavelength onto the photosensitive layer in a spatially registered relationship; and an optical filter having a wavevector-dependent transfer function disposed in an optical path of the second optical radiation and configured to receive, at the second wavelength, an optical field patterned by the mask and to modify spatial-frequency content of the optical field such that the second patterned image has an edge-emphasizing intensity profile derived from the pattern, where the edge-emphasizing intensity profile overlaps edge regions of the first patterned image, wherein superposition of the first patterned image and the second patterned image on the photosensitive layer suppresses exposure at the edge regions of the first patterned image, leaving a narrower exposure region than projection of the first patterned image alone.

Clause 2. The system of clause 1, wherein the first patterned image is an activation image and the second patterned image is a deactivation image, and overlap of the activation image and the deactivation image narrows an exposed region relative to exposure by the activation image alone to provide a feature having a critical dimension below a diffraction-limited critical dimension obtainable from the activation image alone.

Clause 3. The system of clause 1 or 2, wherein the system is configured to expose the photosensitive layer by projecting the first patterned image and the second patterned image in a common exposure operation such that the second patterned image suppresses exposure at edge regions of the first patterned image.

Clause 4. The system of any one of clauses 1-3, wherein the optical filter is positioned adjacent to the mask.

Clause 5. The system of any one of clauses 1-3, wherein the optical filter is positioned at an image plane optically conjugate to the mask.

Clause 6. The system of clause 5, wherein the optical filter comprises a spiral phase plate configured to generate, at the second wavelength, a point spread function having a central intensity minimum and an annular intensity distribution.

Clause 7. The system of any one of clauses 1-6, wherein the projection optics comprise a first optical train and a second optical train configured to respectively project the first patterned image and the second patterned image, the second optical train including the optical filter and the first optical train omitting the optical filter.

Clause 8. The system of clause 7, wherein the first optical train and the second optical train are configured for simultaneous projection of the first patterned image and the second patterned image onto the photosensitive layer.

Clause 9. The system of any one of clauses 1-8, further comprising an alignment subsystem configured to maintain registration between the first patterned image and the second patterned image on the photosensitive layer.

Clause 10. The system of clause 9, wherein the alignment subsystem is configured to periodically realign the first patterned image and the second patterned image between exposure operations.

Clause 11. The system of any one of clauses 1-10, wherein the optical filter comprises a single optical element disposed in a common optical train for the first optical radiation and the second optical radiation, the single optical element having a first transfer function at the first wavelength and a second transfer function at the second wavelength, the first transfer function passing first-wavelength radiation patterned by the mask substantially without spatial-frequency filtering and the second transfer function spatially filtering second-wavelength radiation patterned by the mask to generate the edge-emphasizing intensity profile of the second patterned image.

Clause 12. The system of any one of clauses 1-11, wherein the optical filter is configured to implement a high-pass spatial filtering operation approximating a second-order spatial derivative of the pattern.

Clause 13. The system of any one of clauses 1-12, wherein the optical filter comprises a periodic metasurface.

Clause 14. The system of any one of clauses 1-13, wherein the optical filter comprises a thin-film filter comprising a plurality of layers.

Clause 15. The system of any one of clauses 1-14, wherein the optical filter is inverse-designed to provide the second patterned image with a profile corresponding to a desired patterning resolution.

Clause 16. A method of forming a feature in a photosensitive layer on a substrate using projection lithography, the method comprising: projecting, from a pattern defined by a mask, a first patterned image at a first wavelength onto the photosensitive layer; directing an optical field patterned by the mask to an optical filter having a wavevector-dependent transfer function, where the optical field is at a second wavelength different from the first wavelength; spatially filtering the optical field to generate a second patterned image having an edge-emphasizing intensity profile derived from the pattern; projecting the second patterned image onto the photosensitive layer in registration with the first patterned image such that the second patterned image overlaps edge regions of the first patterned image; and superposing the first patterned image and the second patterned image on the photosensitive layer to suppress exposure at the edge regions of the first patterned image and leave a narrower exposure region than projection of the first patterned image alone.

Clause 17. The method of clause 16, wherein the first patterned image is an activation image and the second patterned image is a deactivation image.

Clause 18. The method of clause 16 or 17, wherein projecting the first patterned image and projecting the second patterned image comprises simultaneously projecting the first patterned image and the second patterned image onto the photosensitive layer.

Clause 19. The method of any one of clauses 16-18, further comprising periodically realigning the first and second patterned images between exposure operations.

Clause 20. The method of any one of clauses 16-19, wherein directing the optical field to the optical filter comprises directing the optical field to an optical filter disposed adjacent to the mask.

Clause 21. The method of any one of clauses 16-19, wherein directing the optical field to the optical filter comprises directing the optical field to an optical filter positioned at an image plane optically conjugate to the mask.

Clause 22. The method of clause 21, wherein the optical filter comprises a spiral phase plate configured to generate, at the second wavelength, a point spread function having a central intensity minimum and an annular intensity distribution.

Clause 23. The method of any one of clauses 16-22, wherein spatially filtering the optical field comprises implementing a high-pass spatial filtering operation approximating a second-order spatial derivative of the pattern.

Clause 24. The method of any one of clauses 16-23, wherein the optical filter comprises a periodic metasurface.

Clause 25. The method of any one of clauses 16-24, wherein the optical filter comprises a thin-film filter comprising a plurality of layers.

Clause 26. A projection lithography apparatus for exposing a photosensitive layer on a substrate, comprising: a mask defining a pattern; a first radiation source configured to provide first optical radiation at a first wavelength; a second radiation source configured to provide second optical radiation at a second wavelength different from the first wavelength; a first optical train configured to project, from the pattern defined by the mask, a first patterned image at the first wavelength onto the photosensitive layer, the first optical train omitting an optical filter; a second optical train configured to project, from the pattern defined by the mask, a second patterned image at the second wavelength onto the photosensitive layer, the second optical train including an optical filter having a wavevector-dependent transfer function configured to modify spatial-frequency content of a mask-patterned optical field at the second wavelength such that the second patterned image has an edge-emphasizing intensity profile derived from the pattern; and an alignment subsystem configured to maintain registration between the first patterned image and the second patterned image on the photosensitive layer, wherein superposition of the first patterned image and the second patterned image on the photosensitive layer suppresses exposure at edge regions of the first patterned image and leaves a narrower exposure region than projection of the first patterned image alone.

Clause 27. The apparatus of clause 26, wherein the first patterned image is an activation image and the second patterned image is a deactivation image.

Clause 28. The apparatus of clause 26 or 27, wherein the first optical train and the second optical train are configured for simultaneous projection of the first patterned image and the second patterned image onto the photosensitive layer.

Clause 29. The apparatus of any one of clauses 26-28, wherein the alignment subsystem is configured to periodically realign the first patterned image and the second patterned image between exposure operations.

Clause 30. The apparatus of any one of clauses 26-29, wherein the optical filter is disposed adjacent to the mask in the second optical train.

Clause 31. The apparatus of any one of clauses 26-29, wherein the optical filter is positioned at an image plane optically conjugate to the mask in the second optical train.

Clause 32. The apparatus of clause 31, wherein the optical filter comprises a spiral phase plate configured to generate, at the second wavelength, a point spread function having a central intensity minimum and an annular intensity distribution.

Clause 33. The apparatus of any one of clauses 26-32, wherein the optical filter implements a high-pass spatial filtering operation approximating a second-order spatial derivative of the pattern.

Clause 34. The apparatus of any one of clauses 26-33, wherein the optical filter comprises a periodic metasurface.

Clause 35. The apparatus of any one of clauses 26-34, wherein the optical filter comprises a thin-film filter comprising a plurality of layers.

Clause 36. A lithographic mask assembly for two-color projection lithography, comprising: a mask defining a pattern; and a wavevector-based optical filter disposed adjacent to the mask and having a wavevector-dependent transfer function, wherein the optical filter is configured to: receive an optical field patterned by the mask at a second wavelength different from a first wavelength used in the two-color projection lithography, and modify spatial-frequency content of the optical field, such that the mask assembly transmits a patterned optical field having an edge-emphasizing intensity profile derived from edge regions of the pattern.

Clause 37. The lithographic mask assembly of clause 36, wherein the optical filter is configured to implement a high-pass spatial filtering operation approximating a second-order spatial derivative of the pattern.

Clause 38. The lithographic mask assembly of clause 36 or 37, wherein the optical filter comprises a periodic metasurface.

Clause 39. The lithographic mask assembly of any one of clauses 36-38, wherein the optical filter is inverse-designed to provide the patterned optical field transmitted by the mask assembly with a profile corresponding to a desired patterning resolution.

Clause 40. The lithographic mask assembly of any one of clauses 36-39, wherein the optical filter comprises a thin-film filter comprising a plurality of layers.

What is claimed is:

1. A projection lithography system for forming a feature in a photosensitive layer on a substrate, comprising:
a mask defining a pattern;
a first radiation source configured to provide first optical radiation at a first wavelength;
a second radiation source configured to provide second optical radiation at a second wavelength different from the first wavelength;
projection optics configured to project, from the pattern defined by the mask, a first patterned image at the first wavelength and a second patterned image at the second wavelength onto the photosensitive layer in a spatially registered relationship; and
an optical filter having a wavevector-dependent transfer function disposed in an optical path of the second optical radiation and configured to receive, at the second wavelength, an optical field patterned by the mask and to modify spatial-frequency content of the optical field such that the second patterned image has an edge-emphasizing intensity profile derived from the pattern, where the edge-emphasizing intensity profile overlaps edge regions of the first patterned image,
wherein superposition of the first patterned image and the second patterned image on the photosensitive layer suppresses exposure at the edge regions of the first patterned image, leaving a narrower exposure region than projection of the first patterned image alone.

2. The system of claim 1, wherein the first patterned image is an activation image and the second patterned image is a deactivation image, and overlap of the activation image and the deactivation image narrows an exposed region relative to exposure by the activation image alone to provide a feature having a critical dimension below a diffraction-limited critical dimension obtainable from the activation image alone.

3. The system of claim 1, wherein the system is configured to expose the photosensitive layer by projecting the first patterned image and the second patterned image in a common exposure operation such that the second patterned image suppresses exposure at edge regions of the first patterned image.

4. The system of claim 1, wherein the optical filter is positioned adjacent to the mask.

5. The system of claim 1, wherein the optical filter is positioned at an image plane optically conjugate to the mask.

6. The system of claim 5, wherein the optical filter comprises a spiral phase plate configured to generate, at the second wavelength, a point spread function having a central intensity minimum and an annular intensity distribution.

7. The system of claim 1, wherein the projection optics comprise a first optical train and a second optical train configured to respectively project the first patterned image and the second patterned image, the second optical train including the optical filter and the first optical train omitting the optical filter.

8. The system of claim 7, wherein the first optical train and the second optical train are configured for simultaneous projection of the first patterned image and the second patterned image onto the photosensitive layer.

9. The system of claim 7, further comprising an alignment subsystem configured to maintain registration between the first patterned image and the second patterned image on the photosensitive layer.

10. The system of claim 9, wherein the alignment subsystem is configured to periodically realign the first patterned image and the second patterned image between exposure operations.

11. The system of claim 1, wherein the optical filter comprises a single optical element disposed in a common optical train for the first optical radiation and the second optical radiation, the single optical element having a first transfer function at the first wavelength and a second transfer function at the second wavelength, the first transfer function passing first-wavelength radiation patterned by the mask substantially without spatial-frequency filtering and the second transfer function spatially filtering second-wavelength radiation patterned by the mask to generate the edge-emphasizing intensity profile of the second patterned image.

12. The system of claim 1, wherein the optical filter is configured to implement a high-pass spatial filtering operation approximating a second-order spatial derivative of the pattern.

13. The system of claim 1, wherein the optical filter comprises a periodic metasurface.

14. The system of claim 1, wherein the optical filter comprises a thin-film filter comprising a plurality of layers.

15. The system of claim 1, wherein the optical filter is inverse-designed to provide the second patterned image with a profile corresponding to a desired patterning resolution.

16. A method of forming a feature in a photosensitive layer on a substrate using projection lithography, the method comprising:
projecting, from a pattern defined by a mask, a first patterned image at a first wavelength onto the photosensitive layer;
directing an optical field patterned by the mask to an optical filter having a wavevector-dependent transfer function, where the optical field is at a second wavelength different from the first wavelength;
spatially filtering the optical field to generate a second patterned image having an edge-emphasizing intensity profile derived from the pattern;
projecting the second patterned image onto the photosensitive layer in registration with the first patterned image such that the second patterned image overlaps edge regions of the first patterned image; and
superposing the first patterned image and the second patterned image on the photosensitive layer to suppress exposure at the edge regions of the first patterned image and leave a narrower exposure region than projection of the first patterned image alone.

17. The method of claim 16, wherein the first patterned image is an activation image and the second patterned image is a deactivation image.

18. The method of claim 16, wherein projecting the first patterned image and projecting the second patterned image comprises simultaneously projecting the first patterned image and the second patterned image onto the photosensitive layer.

19. The method of claim 18, further comprising periodically realigning the first and second patterned images between exposure operations.

20. The method of claim 16, wherein directing the optical field to the optical filter comprises directing the optical field to an optical filter disposed adjacent to the mask.

21. The method of claim 16, wherein directing the optical field to the optical filter comprises directing the optical field to an optical filter positioned at an image plane optically conjugate to the mask.

22. The method of claim 21, wherein the optical filter comprises a spiral phase plate configured to generate, at the second wavelength, a point spread function having a central intensity minimum and an annular intensity distribution.

23. The method of claim 16, wherein spatially filtering the optical field comprises implementing a high-pass spatial filtering operation approximating a second-order spatial derivative of the pattern.

24. The method of claim 16, wherein the optical filter comprises a periodic metasurface.

25. The method of claim 16, wherein the optical filter comprises a thin-film filter comprising a plurality of layers.
